(19) United States
(12) Patent Application Publication
(10) Pub. No.: US 2017/0156008 A1
(43) Pub. Date: Jun. 1, 2017

(54) TRANSDUCER ELEMENT AND METHOD OF MANUFACTURING A TRANSDUCER ELEMENT

(71) Applicant: Epcos AG, München (DE)

(72) Inventor: Kurt Rasmussen, Herlev (DK)

(21) Appl. No.: 15/320,216

(22) PCT Filed: Jul. 17, 2014
(86) PCT No.: PCT/EP2014/065441

§ 371 Date: Dec. 19, 2016

(51) Int. Cl. H04R 19/04; B81C 1/00; B81B 7/00; H04R 19/00; H04R 31/00

(52) U.S. Cl. CPC H04R 19/04; H04R 19/005; H04R 31/006; B81B 7/007; B81C 1/00158; H04R 2201/003; B81B 2201/0257; B81B 2203/0127; B81B 2203/0315; B81C 2201/0104; B81C 2201/0176

(57) ABSTRACT

The present invention concerns a transducer element (1) which comprises a substrate (5) which comprises a cavity (23) extending through the substrate (5), a backplate (3) which is arranged in the cavity (23) of the substrate (5) and a membrane (2) which is movable relative to the backplate (3). Further, the present invention concerns a method of manufacturing a transducer element (1).

The present invention concerns a transducer element and a method of manufacturing a transducer element.

It is an object of the present invention to provide an improved transducer element which allows for an easier manufacturing process and/or which is easier to mount on a substrate by a flip-chip process, e.g. due to reduced internal stress.

This object is solved by a transducer element according to claim 1 and by a method of manufacturing a transducer element according to the second independent claim.

A transducer element is provided which comprises a substrate comprising a cavity extending through the substrate, a backplate which is arranged in the cavity of the substrate and a membrane which is movable relative to the backplate.

The transducer element may be a MEMS device. The transducer element may be configured to convert an acoustic signal into an electric signal. In particular, the transducer element may be configured to measure a sound pressure being applied to the transducer element. The membrane may be moved relative to the backplate in response to a sound being applied to the transducer element. Thus, the transducer element may be used in a MEMS microphone.

The membrane and the backplate may form a capacitor wherein the capacitance of the capacitor is variable depending on a sound pressure being applied to the transducer element.

The cavity is an opening which extends from an upper surface of the substrate to a lower surface of the substrate. The upper surface may face towards to membrane and the lower surface may face away from the membrane. The cavity may further comprise a recess arranged at the upper surface of the substrate. The recess of the substrate may be a deepening formed in the upper surface of the substrate. In particular, the area of the substrate outside of the recess may be flat and the recess may be offset relative to the flat area away from the membrane.

In particular, the backplate may be arranged in the recess which forms a part of the cavity.

Arranging the backplate in the cavity of the substrate provides various advantages. It allows reducing the topography of the transducer element. The topography is defined as the maximum height difference between contact pads of the transducer element. Each of the substrate, the backplate and the membrane is connected to a contact pad for providing a voltage to the respective element. The term “height” refers to the height of the respective element measured from the lower surface of the substrate.

By arranging the backplate in the cavity, a transducer element is constructed wherein the height difference between the contact pads of the substrate and the backplate is very low as the backplate and the substrate have a similar height. Thus, the topography of the transducer element is reduced. A reduced topography results in reduced internal stresses when mounting the transducer element in flip-chip technique on a substrate. Further, the bondability of the transducer element is improved thereby.

Moreover, arranging the backplate in the cavity of the substrate significantly reduces the amount of oxide required for insulation and planarization of the transducer element. The cavity only has to be partly covered with an oxide layer. In particular, only parts of the recess have to be covered with an oxide. This arrangement allows to omit an oxide layer covering the entire upper surface of the substrate. As no oxide layer covering the entire upper surface of the substrate is required, the compressive stress which is typically exerted by an oxide layer onto a transducer element is significantly reduced. Thus, no compensation layer for said compressive stress is required on the backside of the substrate. As no compensation layer is required on the backside, the step of thinning the substrate can be moved to the end of the manufacturing process. Thus, it is possible to carry out the most manufacturing steps with a relatively thick wafer which is significantly easier to handle in CMOS process environments.

As discussed above, the reduced amount of oxide required for insulation and planarization of the transducer element results in less compressive stresses being applied to the transducer element. Thus, a bow of a wafer from which the transducer element is manufactured is reduced. This bow is also referred to as the wafer bow. The transducer element is manufactured out of a wafer. In particular, a plurality of transducer elements is manufactured out of a wafer simultaneously. The reduced wafer bow also reduces material breakage during manufacturing such that the manufacturing process becomes more reliable and less deficient products are manufactured.

Another advantage of arranging the backplate in the cavity is that the overall amount of compressive oxide arranged on the substrate surface is reduced. Accordingly, no oxide layer is required on the lower surface of the substrate to even out the stress exerted on the upper surface of the substrate. Thus, the construction of a transducer element with a reduced height is enabled. Thereby, a very compact transducer element is provided which is advantageous in applications with limited space available.

The backplate can either be a lower backplate in a double backplate transducer element or the only backplate in a single backplate transducer element. The backplate is not movable relative to the substrate. The membrane is typically fixed to the transducer element such that an outer area of the membrane cannot move in a direction perpendicular to the backplate. However, an interior area of the membrane which is adjacent to the outer area is movable in a direction perpendicular to the backplate.

In one embodiment, the substrate comprises an upper surface which faces towards the membrane and the backplate comprises an upper surface which faces towards the membrane, wherein the upper surface of the substrate and the upper surface of the backplate are on the same level. In particular, the upper surfaces are in-plane or flush. In other words, the upper surface of the substrate and the upper surface of the backplate have the same height. Thereby, the topography of the transducer element is reduced as the substrate and the backplate are on the same level.

The substrate may have a thickness of 500 μm or less. In particular, the substrate may have a thickness of 450 μm or less. The substrate may have a thickness in the range of 200 μm to 500 μm. The ongoing trend towards an increased miniaturization requires transducer elements with very low substrate thicknesses. Accordingly, providing a transducer element with such a low thickness of the substrate fulfils the requirements regarding miniaturization. As discussed above, the backplate being arranged in the cavity of the substrate reduces internal stress during flip-chip mounting. Thus, the requirements regarding an inner stability of the transducer element are less strict, thereby allowing for a low substrate thickness.

A first contact pad may be arranged on the backplate and a second contact pad may be arranged on the membrane wherein the first and the second contact pad are on the same level. The first contact pad is used for electrically connecting the backplate and applying a certain voltage to the backplate. The second contact pad is used for electrically connecting the membrane and is configured for applying a voltage to the membrane. As the first and the second contact pads are on the same level, they allow for a symmetric and robust flip-chip process when assembling the transducer element to a further member, e.g. the substrate of a MEMS microphone.

Further, a third contact pad may be arranged on the substrate of the transducer element wherein the third contact pad is on the same level as the first and the second contact pad. Thereby, the topography of the transducer element is further reduced. In particular, the topography of the transducer element may be 5 μm or less.

The transducer element may further comprise a second backplate which is arranged on the side of the membrane which faces away from the substrate. Accordingly, the transducer element may be a double backplate transducer element. Double backplate transducer elements typically provide an improved sensitivity and an improved signal-to-noise ratio.

Further, a MEMS microphone is provided comprising the above-described transducer element.

A second aspect of the present invention concerns a method of manufacturing a transducer element.

The transducer element manufactured by said method may be the above-described transducer element. Thus, every structural and functional feature disclosed with respect to the transducer element may also be present with respect to the method. Vice versa, every structural and functional feature disclosed with respect to the method may also be present with respect to the transducer element.

The method comprises the steps of providing a substrate, forming a recess in the substrate, arranging a backplate in the recess, forming a membrane above the backplate such that the membrane is movable relative to the backplate and forming a cavity that extends through the substrate from a lower surface of the substrate which faces away from the membrane into the recess. The steps may be carried out in the order as given above.

The recess may be formed by etching. Etching allows to form the recess very precise with a desired depth and in a desired shape.

By arranging the backplate in the cavity, the method provides the above-discussed advantages of a reduced topography and of a low amount of oxide on the substrate, resulting in a reduced wafer bow and allowing for a thin substrate.

The step of arranging the backplate in the recess may comprise the sub-steps of depositing an insulation oxide layer such that the insulation oxide layer covers an upper surface of the substrate, depositing a layer that is configured to form the backplate in a later manufacturing step such that the layer covers an upper surface of the insulation oxide layer and removing the layer and the insulation oxide layer outside of the recess such that the layer forms the backplate. The upper surface of the insulation oxide layer faces away from the substrate.

As the layer and the insulation oxide layer are removed outside of the recess, the insulation oxide layer does not exert a lot of compressive stress onto the substrate.

The layer and the insulation oxide layer may be removed by chemical mechanical polishing. Thereby, the substrate which may comprise silicon may be the stop-layer. As the substrate has a large surface, this allows very good control of the chemical mechanical polishing.

Further, the method may comprise the steps of structuring the backplate, depositing a planarization layer such that the planarization layer covers the structured backplate and the upper surface of the substrate and partly removing the planarization layer such that an upper surface of the backplate and the upper surface of the substrate are free of the planarization layer. The planarization layer may be an oxide layer. The planarization layer ensures that the transducer element has a flat surface after said steps are carried out. Moreover, as the backplate is arranged in the recess, the planarization layer does not have to cover the upper surface of the substrate such that it does not exert compressive stress onto the substrate.

The planarization layer may be partly removed by chemical mechanical polishing. The upper surface of the substrate and the upper surface of the backplate may form stop-layers for the chemical mechanical polishing. As the substrate and the backplate have a large surface area, resulting in a large stopping area, the process of chemical mechanical polishing is very well controllable, and, thus, the thickness of the polished surfaces remains uniform.

The planarization layer may be deposited by low pressure chemical vapour deposition (LPCVD) or by plasma enhanced chemical vapour deposition (PECVD). Each of said methods allows to deposit a thin layer with high precision. PECVD deposition is a single side process. In a LPCVD process a layer is deposited at both sides of the substrate. Accordingly, in a LPCVD process, the layer deposited at the lower surface of the substrate has to be removed.

Further, the method may comprise the step of thinning the substrate which is carried out after the backplate and the membrane have been formed and after the backplate has been structured. Accordingly, the step of thinning the substrate can be carried out at the end of the manufacturing process, thereby allowing to handle the substrate in a rather thick form during the manufacturing process. This reduces the danger of damaging the transducer element during the manufacturing process. Moreover, as the substrate can be handled in a rather thick form during the manufacturing process, the method enables the use of standard handling equipment during the manufacturing process. In particular, the method does not require special manufacturing tools for thin and fragile wafers. Carrying out the thinning step at the end of the manufacturing process is only possible because arranging the transducer element in the cavity makes it possible to abstain from providing a compensation layer for the oxide layer on the back side of the transducer element, i.e. on the lower surface of the substrate.

The thickness of the substrate may be reduced to 500 μm or less in the step of thinning the substrate. In particular, the thickness of the substrate may be reduced to the range of 200 to 500 μm in the step of thinning. Before the step of thinning the substrate, the substrate may have a thickness in the range of 500 to 900 μm.

The substrate may be thinned by a grinding wheel, wherein a grid size of the grinding wheel is chosen to form a thin compressive stressed layer on a lower surface of the substrate. The thin compressive stressed layer may contribute to the reduction of the waferbow. In principle, the thin compressive stressed layer acts the same way as using a slightly thicker wafer on the waferbow.

In the following, the invention is described in further detail with the help of the figures.

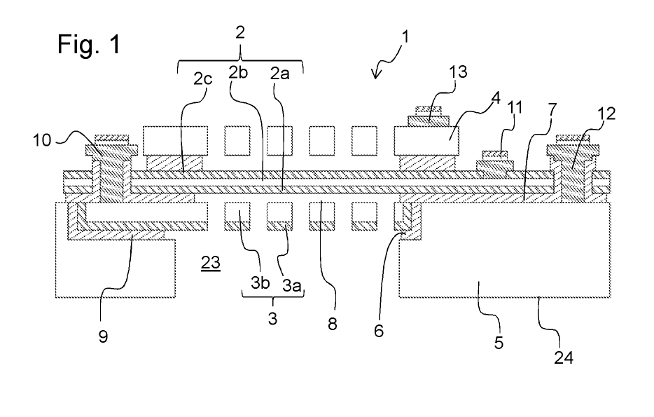

FIG. 1 shows a transducer element.

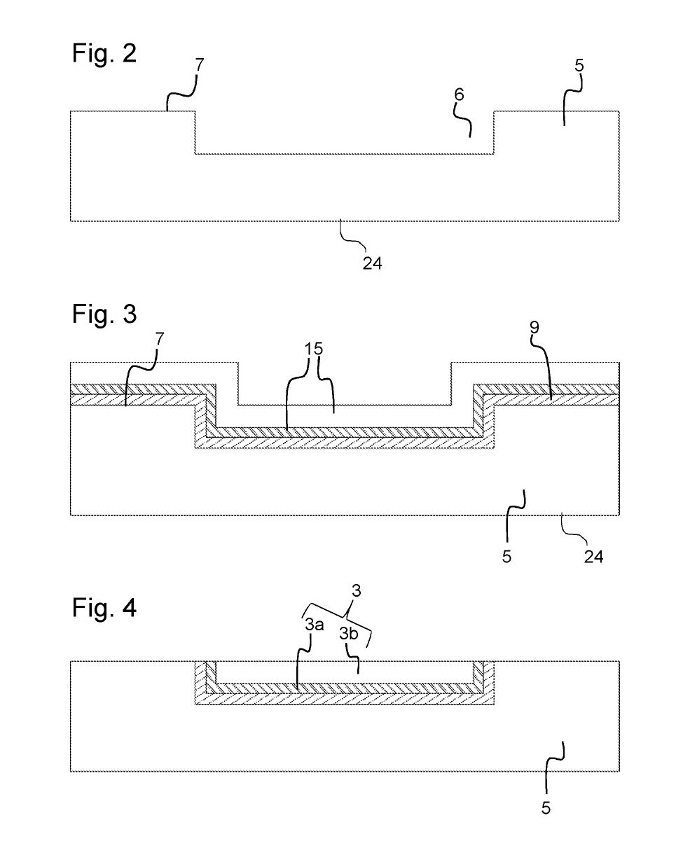

FIGS. 2 to 14 show the transducer element at different stages of the manufacturing process.

FIG. 1 shows a transducer element 1. The transducer element 1 is a MEMS element. The transducer element 1 may be used in a MEMS microphone. In particular, the transducer element 1 is configured to convert an acoustic signal into an electrical signal.

The transducer element 1 comprises a movable membrane 2, a lower backplate 3 and an upper backplate 4. The membrane 2 is movable relative to the lower backplate 3 and relative to the upper backplate 4. The lower backplate 3 and the upper backplate 4 are fixed. In particular, the lower backplate 3 and the upper backplate 4 are not moveable relative to a substrate 5.

A voltage can be applied between the membrane 2 and the lower backplate 3. The membrane 2 and the lower backplate 3 are configured to form a capacitor. Further, another voltage can be applied between the membrane 2 and the upper backplate 4. Thus, the membrane 2 and the upper backplate 4 are also configured to form a capacitor. The capacitance of each of said capacitors is variable depending on a variation in the sound pressure applied to the transducer element 1, e.g. variable in response to a sound being applied to the transducer element 1.

The transducer element 1 shown in FIG. 1 is also referred to as a double backplate transducer element. In an alternative design, the transducer element 1 may comprise only one of the lower backplate 3 and the upper backplate 4. Accordingly, the transducer element 1 may also be a single backplate transducer element. This single backplate transducer element has the membrane 2 on the side facing away from the substrate 5. This is very feasible for a flip chip mounted bottom port microphone.

The transducer element 1 can be used in a microphone. The transducer element 1 defines a front volume. The front volume is acoustically connected to a surrounding of the microphone. In particular, the microphone is configured such that sound can travel to the front volume of the transducer element 1. Moreover, the transducer element 1 defines a back volume. The back volume of the transducer element 1 is a reference volume which is acoustically separated from the front volume. The transducer element 1 is configured to measure a difference between the sound pressure in the front volume and the sound pressure in the back volume.

Further, the transducer element 1 comprises the substrate 5. In particular, the substrate 5 is a silicon bulk. The substrate 5 comprises a cavity 23. The cavity 23 is an opening which extends through the substrate. In particular, the cavity 23 extends from a lower surface 24 of the substrate 5 which faces away from the membrane 2 to an upper surface 7 of the substrate 5 which faces towards the membrane 2.

The substrate 5 further comprises a recess 6. The cavity 23 fades into the recess 6 such that the recess 6 becomes part of the cavity 23. The recess 6 is an area of the substrate 5 which has a reduced height. The recess 6 is arranged at the upper surface 7 of the substrate. The lower backplate 3 is arranged in the recess 6 of the substrate 5. In particular, an upper surface 8 of the lower backplate 3 which faces towards the membrane 2 is arranged in the same plane as the upper surface 7 of the substrate 5.

The lower backplate 3 comprises a first sub-layer 3a consisting of silicon nitride and a second sub-layer 3b comprising in-situ P-doped polysilicon. The first sub-layer 3a has a thickness in the range of 0.5 μm to 1.5 μm and a medium stress in the range of 400 to 500 MPa. The second sub-layer 3b has a thickness in the range of 1.0 μm to 2.0 μm.

The membrane 2 comprises multiple sub-layers. In particular, the membrane comprises a stack comprising a first sub-layer 2a, a second sub-layer 2b and a third sub-layer 2c. The first sub-layer 2a comprises silicon nitride. The second sub-layer 2b comprises P-poly. The third sub-layer 2c comprises silicon nitride.

An insulation oxide layer 9 is arranged between the lower backplate 3 and the substrate 5. The insulation oxide layer 9 prevents an electrical short-circuit between the lower backplate 3 and the substrate 5 when a voltage is applied between the lower backplate 3 and the substrate 5.

Further, a first contact pad 10 is arranged on the lower backplate 3. A second contact pad 11 is arranged on the membrane 2. A third contact pad 12 is arranged on the substrate 5. Each of the first, the second and the third contact pads 10, 11, 12 have the same height. Thus, it is easier to mount the transducer element 1 using a flip-chip technique. Furthermore, a fourth contact pad 13 is arranged on the upper backplate 4. The fourth contact pad 13 has a height which is different from the height of the first, the second and the third contact pad 10, 11, 12. However, the height difference between the fourth contact pad 13 and the other contact pads 10, 11, 12 is small.

As the height difference between the four contact pads 10, 11, 12, 13 is small, the bondability of the transducer element 1 is improved. Moreover, the occurrence of non-symmetric stress on the transducer element 1 is reduced, when mounting the transducer element 1 with the use of a flip-chip technique and solder processes.

In the following, the manufacturing process of the transducer element 1 is discussed with respect to FIGS. 2-14 which show different stages of the manufacturing process.

FIG. 2 shows a first stage at the beginning of the manufacturing process. Here, the substrate 5 is provided. At this stage of the manufacturing process, the substrate 5 is relatively thick, thereby facilitating the handling of the substrate 5 in a standard CMOS process environment. In particular, the substrate has a thickness in the range of 500 to 900 μm.

Further, the recess 6 is formed at the upper surface 7 of the substrate 5. The recess 6 has a depth which is equal to or larger than the height of the lower backplate 3 (not shown in FIG. 2). The recess 6 is formed by etching.

FIG. 3 shows the transducer element 1 in a later manufacturing stage. First a thin layer (not shown) of oxidation phosphorous implants is applied on the upper surface 7 of the substrate 5 and afterwards removed again. In particular, applying and removing this layer comprises the sub-steps of depositing a thin thermal oxide layer with a thickness about 100 nm, than implantation of phosphor, than annealing and afterwards, removal or etching of the oxide layer. This layer serves the purpose to reduce a contact resistance between the substrate 5 and the corresponding third contact pad 12 which is applied later. Afterwards, the insulation insulation oxide layer 9 is deposited on the upper surface 7 of the substrate 5 such that the insulation insulation oxide layer 9 covers the upper surface 7 of the substrate 5 and the recess 6.

Next, a layer 15 is deposited which is configured to form the lower backplate 3 in a later manufacturing step. The layer 15 is deposited over the whole area of the substrate 5 including the recess 6. The layer 15 comprises multiple sub-layers. In particular, the layer 15 comprises sub-layers which are configured to form the above described sub-layers 3a, 3b in a later manufacturing step.

FIG. 4 shows the transducer element 1 after a next manufacturing step has been carried out wherein the layer 15 which is configured to form the lower backplate 3 and the insulation oxide layer 9 are partly removed. In particular, the layer 15 and the insulation oxide layer 9 are removed in the areas of the substrate 5 which are not part of the recess 6. These areas are also called scribe lane.

In particular, the layer 15 and the insulation oxide layer 9 are removed by chemical mechanical polishing. The chemical mechanical polishing is configured to remove polysilicon, silicon nitride and silicon oxide and to stop on a silicon layer. Thus, the upper surface 7 of the substrate 5 forms a stop-layer for the chemical mechanical polishing. The chemical mechanical polishing is designed to stop such that only the lower backplate 3 remains off the layer 15. In particular, the upper surface 8 of the lower backplate 3 is at the same level as the upper surface 7 of the substrate 5 after the step of chemical mechanical polishing.

As the upper surface 7 of the substrate 5 which forms the stop-layer for the chemical mechanical polishing has a large area, the step of chemical mechanical polishing is very well controllable.

Moreover, there is no risk of oxide erosion, as there is no oxide present in the areas of the substrate 5 outside the recess 6 after the step of chemical mechanical polishing.

Further, the areas of the substrate 5 outside of the recess 6 are free of the insulation oxide layer 9 after the step of chemical mechanical polishing. Oxide typically exerts a large compressive stress on a substrate. As the insulation oxide layer 9 has been removed from the areas of the substrate 5 outside of the recess 6, the amount of compressive stressed oxide on the upper surface 7 of the substrate 5 is significantly reduced. Thus, the substrate 5 is less likely to be deformed by said stress. Thus, the overall bow of a wafer is reduced when producing the transducer elements 1 from a wafer.

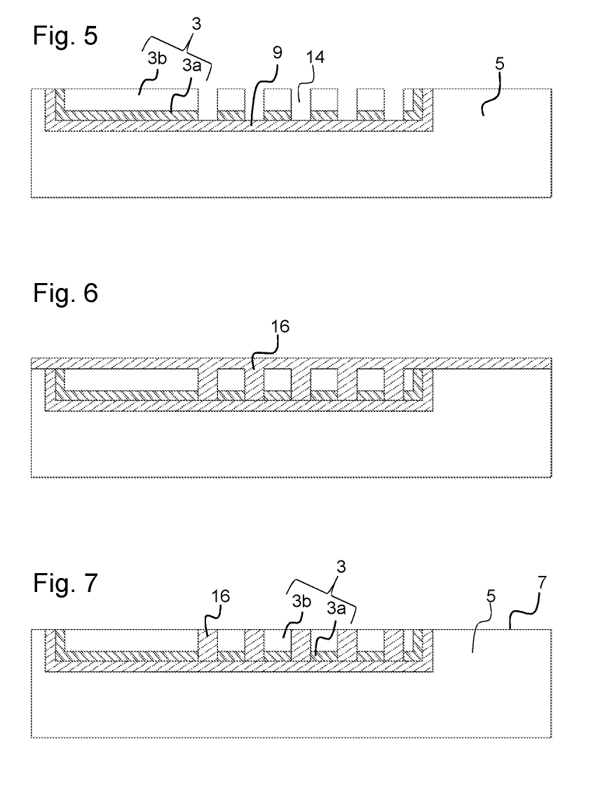

FIG. 5 shows the transducer element 1 after a next manufacturing step. In this manufacturing step, the lower backplate 3 has been structured. In particular, sound entry openings 14 are formed in the lower backplate 3.

FIG. 6 shows the transducer element after a next manufacturing step has been carried out. A planarization layer 16 has been deposited over the structured backplate 3 and the substrate 5 such that the planarization layer 16 covers the structured backplate 3 and the substrate 5. The planarization layer 16 comprises oxide.

The transducer element 1 has a uniform thickness after the planarization layer 16 has been applied. The planarization layer 16 is applied by plasma enhanced chemical vapour deposition or by low pressure chemical vapour deposition. The planarization layer 16 has a thickness in the range 4 to 5 μm. This step is followed by annealing the planarization layer 16. If a thick planarization layer 16 is deposited by plasma enhanced chemical vapour deposition, the steps of the depositing and annealing will be sequential. This means that 1-2 μm oxide is deposited on the upper surface 7 of the substrate 5 and/or lower surface of the substrate 5 which is opposite to the upper surface 7, then the layer is annealed and the sequence is repeated until the total layer thickness is obtained. The purpose of the deposition of oxide on the lower surface is to compensate for the bow generated due to the planarization layer 16 on the upper surface 7. For a thick wafer, it is not necessary to deposit the same amount of oxide on the lower surface as on the upper surface, as the bow depends on the wafer thickness.

FIG. 7 shows the transducer element 1 after a next manufacturing step has been carried out. In said next manufacturing step, a second chemical mechanical polishing step is carried out to partly remove the planarization layer 16. The lower backplate 3 and the areas of the substrate 5 outside the recess 6 are exposed again and freed from the passivation layer 16.

Again, the upper surface 7 of the substrate 5 which comprises silicon forms the stop-layer for the chemical mechanical polishing step. Moreover, the second sub-layer 3b of the lower backplate 3 comprises polysilicon which has a very low polishing rate. Thus, it forms a quasi stop-layer as its polishing rate is significantly lower than the polishing rate of the planarization layer 16. Thereby, the layer thickness control is improved due to the large area of the stop-layers. In detail, the thickness of the second sub-layer 3b of the lower backplate 3 is reduced only to a small extend such that the thickness of the lower backplate 3 remains uniform.

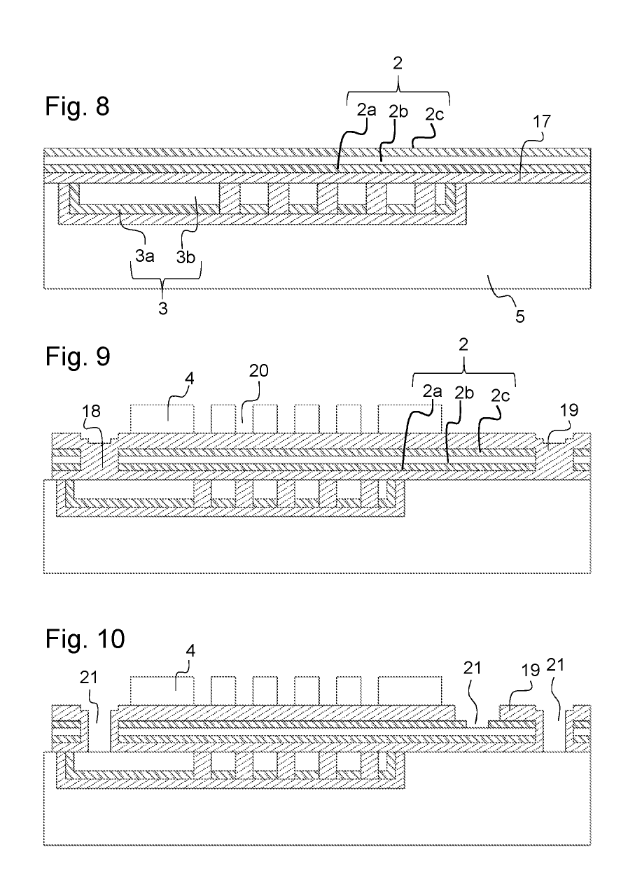

FIG. 8 shows the transducer element 1 after another manufacturing step has been carried out. Here, a sacrificial oxide layer 17 is deposited over the lower backplate 3 and the substrate 5. The sacrificial oxide layer 17 is deposited by plasma enhanced chemical vapour deposition or by low pressure chemical vapour deposition. Afterwards, an optional annealing step may be carried out.

Further, the membrane 2 has been arranged over the sacrificial oxide layer in the manufacturing step. The membrane comprises the above-described stack of multiple sub-layers 2a, 2b, 2c. The step of depositing the membrane 2 may further include annealing steps.

Moreover, FIG. 9 shows the transducer element 1 after a next manufacturing step has been carried out. The membrane 2 has been structured. In particular, parts of the membrane 2 have been removed. Moreover, an opening 18 has been arranged in the membrane 2 which will be used for the first contact pad 10 in a later manufacturing step. The membrane 2 is structured using one or two mask layers depending on the structure needed.

Moreover, a second sacrificial oxide layer 19 has been deposited onto the structured membrane 2. The second sacrificial oxide layer 19 is deposited by plasma enhanced chemical vapour deposition or by low pressure chemical vapour deposition. Optionally, an annealing step may have been carried out.

Further, the upper backplate 4 has been arranged above the second sacrificial oxide layer 19. The upper backplate 4 comprises in-situ P-doped poly. The upper backplate 4 has a thickness of in the range of 2 μm to 4 μm. The upper backplate 4 has an internal stress in the range of 250 to 350 MPa. The upper backplate 4 is deposited using low pressure chemical vapour deposition. Further depositing the upper backplate 4 may include annealing steps.

Furthermore, the upper backplate has been structured. In particular, sound entry openings 20 are formed in the upper backplate 4.

FIG. 10 shows the transducer element after a next manufacturing step has been carried out. Contact holes 21 have been etched into the second sacrificial oxide layer 19. Each of the first contact pad 10 of the lower backplate 3, the second contact pad 11 of the membrane 2 and the third contact pad 12 of the substrate 5 will be arranged in one of the contact holes 21.

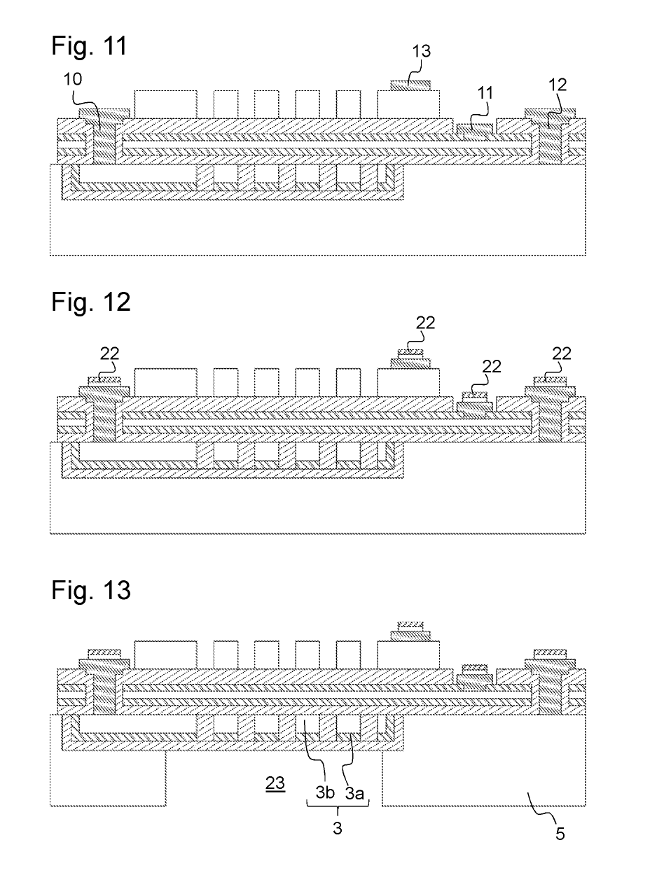

FIG. 11 shows the transducer element after a next manufacturing step has been carried out. Here, the contact pads 10, 11, 12, 13 are created. Each of the contact pads 10, 11, 12, 13 comprises the alloy AlSiCu. In particular, the contact pads 10, 11, 12, 13 have a thickness in the range of 1.0 μm to 2.0 μm.

FIG. 12 shows the transducer element 1 after a next manufacturing step has been carried out. Here, under bump metallizations 22 have been formed on each of the contact pads 10, 11, 12, 13. The under bump metallization 22 comprises Ni—P and Au. The under bump metallization 22 comprise a 3 μm to 5 μm thick layer of electroless NiP and a 50 nm to 100 nm thick layer of electroless Au. The under bump metallization 22 is used for contacting the contact pads 10, 11, 12, 13, e.g. for soldering.

FIG. 13 shows the transducer element after a next manufacturing step has been carried out in which the substrate 5 is thinned. In particular, the step of thinning the substrate 5 reduces the thickness of the substrate 5 to 500 μm or less. The substrate is thinned by a grinding method. The grinding step includes 1000 to 2000 grinds. A grinding wheel is used wherein a final grid size is chosen such that it adds adequate compressive stress to the grinded surface, in order to balance the waferbow to a low value. In particular, the actual grinding wheel grid size can be in the range of 1000-3000. Still the grind size must not be so low that it adds too much roughness to the surface. It is the damage of the top layer that adds a thin compressive layer to the surface.

Moreover, a part of the substrate 5 is removed, e.g. by etching. Thus, the cavity 23 is formed. The cavity 23 is formed such that the lower backplate 3 is arranged in the cavity 23. In particular, the cavity 23 comprises a part which is arranged below the lower backplate 3 and, further, the cavity 23 comprises the recess 6.

At the manufacturing stage shown in FIG. 13, the transducer element 1 has a convex shape due to compressive stress which is exerted by the large amount of compressive stressed oxide arranged on the upper surface 7 of the substrate 5.

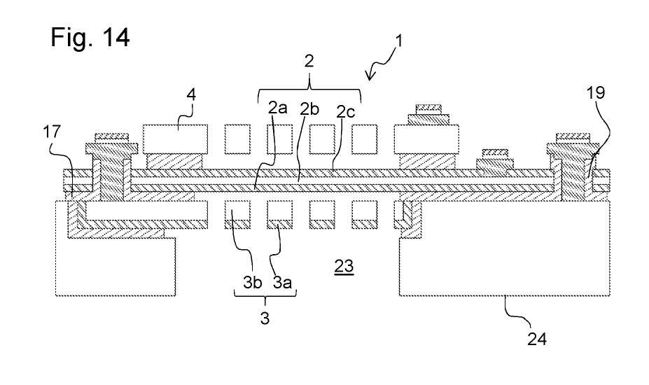

After a last manufacturing step is carried out, the transducer element 1 is manufactured as shown in FIG. 14. In the last manufacturing step, parts of the sacrificial oxide layers 17, 19 are removed, thereby releasing the membrane 2 and the backplates 3, 4 such that the membrane 2 can now be moved relative to the backplates 3, 4.

The upper surface 7 of the substrate 5 is freed from large parts of the sacrificial oxide layers 17, 19. Thus, less compressive stress is exerted on the upper surface 7. Thus, the upper surface 7 changes from a compressive, convex shape into a tensile or concave shape. In particular, the polysilicon has a tensile stress which is now stronger than the compressive stress of the remaining oxide.

At this stage of the manufacturing process, there has established a balance between the tensile and the compressive stress exerted by the different layers such that the bow is reduced to a minimum.

Afterwards a testing step of the transducer element 1 may be carried out.

### REFERENCE NUMERALS

1 transducer element
2 membrane
2a first sub-layer of the membrane
2b second sub-layer of the membrane
2c third sub-layer of the membrane
3 lower backplate
3a first sub-layer of the lower backplate
3b second sub-layer of the lower backplate
4 upper backplate
5 substrate
6 recess
7 upper surface of the substrate
8 upper surface of the lower backplate
9 insulation oxide layer
10 first contact pad
11 second contact pad
12 third contact pad
13 fourth contact pad
14 sound entry opening of the lower backplate
15 layer
16 planarization layer
17 sacrificial oxide layer
18 opening
19 second sacrificial oxide layer
20 sound entry opening of the upper backplate
21 contact hole
22 under bump metallization
23 cavity
24 lower surface of the substrate

1. Transducer element, comprising
a substrate which comprises a cavity extending through the substrate,
a backplate which is arranged in the cavity of the substrate, and
a membrane which is movable relative to the backplate.

2. Transducer element according to claim 1,
wherein the substrate comprises an upper surface which faces towards the membrane,
wherein the backplate comprises an upper surface which faces towards the membrane, and
wherein the upper surface of the substrate and the upper surface of the backplate are on the same level.

3. Transducer element according to claim 1,
wherein the substrate has a thickness of 500 μm or less.

4. Transducer element according to claim 1,
wherein a first contact pad is arranged on the backplate,
wherein a second contact pad is arranged on the membrane, and
wherein the first and the second contact pad are on the same level.

5. Transducer element according to claim 4,
wherein a third contact pad is arranged on the substrate, and
wherein the third contact pad is on the same level as the first and the second contact pad.

6. Transducer element according to claim 1,
further comprising an upper backplate which is arranged on the side of the membrane which faces away from the substrate.

7. MEMS microphone comprising a transducer element wherein the transducer element comprises a substrate which comprises a cavity extending through the substrate, a backplace which is arranged in the cavity of the substrate, and a membrane which is movable relative to the backplate.

8. Method of manufacturing a transducer element, comprising the steps of:
providing a substrate,
forming a recess in the substrate,
arranging a backplate in the recess,
forming a membrane above the backplate such that the membrane is movable relative to the backplate, and
forming a cavity that extends through the substrate from a lower surface of the substrate which faces away from the membrane into the recess.

9. Method according to claim 8,
wherein the step of arranging the backplate in the recess comprises the sub-steps of:
depositing an insulation oxide layer such that the insulation oxide layer covers an upper surface of the substrate,
depositing a layer that is configured to form the backplate in a later manufacturing step such that the layer covers an upper surface of the insulation oxide layer, and
removing the layer and the insulation oxide layer outside of the recess such that the layer forms the backplate.

10. Method according to claim 9,
wherein the layer and the insulation oxide layer are removed by chemical mechanical polishing.

11. Method according to claim 8, further comprising the steps of:
structuring the backplate,
depositing a planarization layer such that the planarization layer covers the structured backplate and the upper surface of the substrate, and
partly removing the planarization layer such that an upper surface of the backplate and the upper surface of the substrate is free of the planarization layer.

12. Method according to claim 11,
wherein the planarization layer is partly removed by chemical mechanical polishing.

13. Method according to claim 11,
wherein the planarization layer is deposited by low pressure chemical vapour deposition or by plasma enhanced chemical vapour deposition.

14. Method according to one of claims 8, further comprising the step of:
thinning the substrate which is carried out after the backplate and the membrane have been formed and after the backplate has been structured.

15. Method according to one of claim 14,
wherein the substrate is thinned by a grinding wheel, wherein a grid size of the grinding wheel is chosen to form a thin compressive stressed layer on a lower surface of the substrate.

16. Method according to claim 8,
wherein the step of arranging the backplate in the recess comprises the sub-steps of:
depositing an insulation oxide layer such that the insulation oxide layer covers an upper surface of the substrate,
depositing a layer that is configured to form the backplate in a later manufacturing step such that the layer covers an upper surface of the insulation oxide layer, and
removing the layer and the insulation oxide layer outside of the recess by chemical mechanical polishing, wherein the upper surface of the substrate forms a stop-layer for the chemical mechanical polishing and wherein the areas of the substrate outside of the recess are free of the insulation oxide layer after the step of chemical mechanical polishing.

17. Method according to claim 9, further comprising the steps of:
structuring the backplate,
depositing a planarization layer such that the planarization layer covers the structured backplate and the upper surface of the substrate, and
partly removing the planarization layer such that an upper surface of the backplate and the upper surface of the substrate is free of the planarization layer.

18. Transducer element according to claim 2, wherein the substrate has a thickness of 500 μm or less.

19. Transducer element according to claim 18,
wherein a first contact pad is arranged on the backplate,
wherein a second contact pad is arranged on the membrane, and
wherein the first and the second contact pad are on the same level.

20. Transducer element according to claim 19, further comprising an upper backplate which is arranged on the side of the membrane which faces away from the substrate.
